(19) United States
(12) Patent Application Publication
(10) Pub. No.: US 2026/0293444 A1
(43) Pub. Date: Sep. 24, 2026

(54) ELECTRONIC DEVICE

(71) Applicant: Samsung Display Co., Ltd., Yongin-si (KR)

(72) Inventors: Junhwan BAE, Yongin-si (KR); Seongjun LEE, Yongin-si (KR); Hongyoub NA, Yongin-si (KR); Dong-Yoon SO, Yongin-si (KR); Jaeeun YU, Yongin-si (KR); Gijung LEE, Yongin-si (KR); Kyung Hyun CHOI, Yongin-si (KR)

(73) Assignee: Samsung Display Co., Ltd., Yongin-si (KR)

(21) Appl. No.: 19/568,207

(22) Filed: Mar. 16, 2026

(30) Foreign Application Priority Data
Mar. 18, 2025 (KR) 10-2025-0034832

(51) Int. Cl. H10K 59/122; H10K 59/38; H10K 59/80; H10K 59/88; H10K 102/00

(52) U.S. Cl. CPC H10K 59/122; H10K 59/38; H10K 59/873; H10K 59/8792; H10K 59/88; H10K 2102/351

(57) ABSTRACT

An electronic device may include a display panel including a first area and a second area adjacent to the first area, the first area including a transmissive area and a light blocking area, and an electronic module under the display panel and overlapping the first area. The display panel may include a first pixel electrode in the light blocking area of the first area, a second pixel electrode in the second area, a first pixel defining layer in the first area and that completely covers the first pixel electrode, and a second pixel defining layer in the second area and including a pixel defining opening corresponding to the second pixel electrode.

### CROSS-REFERENCE TO RELATED APPLICATIONS

This application claims priority under 35 U.S.C. § 119 to Korean Patent

Application No. 10-2025-0034832 filed on Mar. 18, 2025, in the Korean Intellectual Property Office, the disclosures of which are incorporated by reference herein in their entireties.

### BACKGROUND

Example embodiments of the present disclosure described herein relate to electronic devices including a display panel with improved product reliability.

An electronic device may be a device constituted by various electronic components such as a display panel and an electronic module. The electronic module may include a camera, an infrared sensor, and/or a proximity sensor. The electronic module may be disposed under the display panel. One partial area of the display panel may have a higher transmittance than another partial area of the display panel. The electronic module may receive an external input through the one partial area of the display panel or may provide an output through the one partial area of the display panel.

### SUMMARY

Some example embodiments of the present disclosure provide electronic devices including a display panel with improved product reliability.

According to an example embodiment, an electronic device may include a display panel including a first area and a second area adjacent to the first area, the first area including a transmissive area and a light blocking area, and an electronic module under the display panel and overlapping the first area. The display panel may include a first pixel electrode in the light blocking area of the first area, a second pixel electrode in the second area, a first pixel defining layer in the first area and configured to completely cover the first pixel electrode, and a second pixel defining layer in the second area and including a pixel defining opening corresponding to the second pixel electrode.

The display panel may further include a division layer, the division layer being on the first pixel defining layer and the second pixel defining layer, and the division layer includes may include a division opening that is configured to overlap the second pixel electrode.

The division layer further includes a transmissive opening that is configured to overlap the transmissive area, and the division layer may overlap the first pixel electrode.

The electronic device may further include at least two color filters configured to overlap the first pixel electrode.

The at least two color filters may have different colors.

The at least two color filters may not overlap the transmissive area.

The at least two color filters may include a red color filter and a blue color filter.

The at least two color filters may include a red color filter, a blue color filter, and a green color filter.

The display panel may further include a common electrode on the first pixel electrode and the second pixel electrode and an emissive layer between the second pixel electrode and the common electrode.

The first pixel defining layer may be between the first pixel electrode and the common electrode.

The display panel may further include a dummy pixel circuit in the first area and connected with the first pixel electrode and a pixel circuit in the second area and electrically connected with the second pixel electrode.

According to an example embodiment, an electronic device may include a base layer having a first area and a second area defined therein, a circuit layer on the base layer, an element layer on the circuit layer, the element layer including a first pixel electrode in the first area, a second pixel electrode in the second area, a first pixel defining layer in the first area and configured to completely cover the first pixel electrode, and a second pixel defining layer in the second area and including a pixel defining opening corresponding to the second pixel electrode, and an encapsulation layer on the element layer.

The electronic device may further include an anti-reflective layer on the encapsulation layer, and the anti-reflective layer may include a color filter that is configured to overlap the second pixel electrode.

The anti-reflective layer may further include a first color filter that overlaps the first pixel electrode and a second color filter that has a color different from a color of the first color filter and that is on the first color filter.

The anti-reflective layer may further include a third color filter that is on the second color filter and that overlaps the first pixel electrode and has a color different from colors of the first color filter and the second color filter.

The anti-reflective layer may further include a division layer, the division layer may include a division opening configured to overlap the second pixel electrode, and the division layer may overlap the first pixel electrode.

The division layer further may include a transmissive opening that does not overlap the first pixel electrode.

The electronic device may further include an electronic module that is under the base layer and that overlaps the first area.

The encapsulation layer may include a first inorganic encapsulation layer, an organic encapsulation layer on the first inorganic encapsulation layer, and a second inorganic encapsulation layer on the organic encapsulation layer, and a maximum thickness of a portion of the organic encapsulation layer that overlaps the first area may be greater than a maximum thickness of a portion of the organic encapsulation layer that overlaps the second area.

The circuit layer may include a dummy pixel circuit in the first area and connected with the first pixel electrode and a pixel circuit in the second area and electrically connected with the second pixel electrode.

### BRIEF DESCRIPTION OF THE FIGURES

The above and other objects and features of the present disclosure will become apparent by describing in detail some example embodiments thereof with reference to the accompanying drawings.

FIG. 1 is a block diagram of an electronic device according to an example embodiment.

FIG. 2 illustrates schematic views of electronic devices according to various example embodiments.

FIG. 3A is a perspective view of an electronic device according to an example embodiment of the present disclosure.

FIG. 3B is a perspective view of an electronic device according to an example embodiment of the present disclosure.

FIG. 4 is an exploded perspective view of an electronic device according to an example embodiment of the present disclosure.

FIG. 5 is a sectional view of a display device according to an example embodiment of the present disclosure.

FIG. 6 is a plan view of a display panel according to an example embodiment of the present disclosure.

FIG. 7 is an enlarged plan view of a partial area of a display panel according to an embodiment of the present disclosure.

FIG. 8A is a sectional view illustrating the first area of the display panel of FIG. 7, according to an example embodiment of the present disclosure.

FIG. 8B is a sectional view illustrating the second area of a display panel of FIG. 7, according to an example embodiment of the present disclosure.

FIG. 9 is an enlarged plan view of a partial area of a display panel according to an example embodiment of the present disclosure.

FIG. 10 is a sectional view illustrating a first area of a display panel according to an example embodiment of the present disclosure.

FIG. 11 is a sectional view illustrating a first area of a display panel according to an example embodiment of the present disclosure.

FIG. 12 is an enlarged plan view of a partial area of a display panel according to an example embodiment of the present disclosure.

FIG. 13 is an enlarged plan view of a partial area of a display panel according to an example embodiment of the present disclosure.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, some example embodiments of the present disclosure will be described with reference to the accompanying drawings.

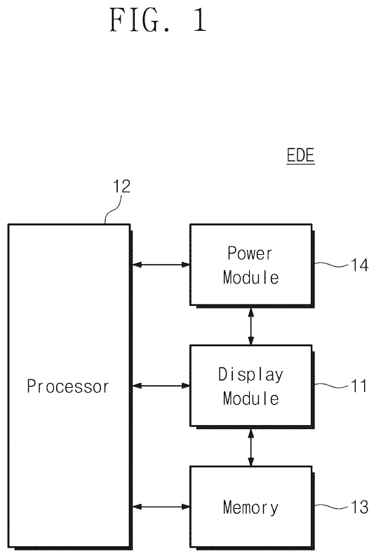

FIG. 1 is a block diagram of an electronic device EDE according to an example embodiment.

Referring to FIG. 1, the electronic device EDE according to an example embodiment may include a display module (interchangeably referred to as a display) 11, a processor (interchangeably referred to as processing circuitry) 12, a memory 13, and a power module (interchangeably referred to as a power supply) 14.

The display module 11 may display an image. The image may include a still image as well as a dynamic image. The processor 12 may include at least one of a central processing unit (CPU), an application processor (AP), a graphic processing unit (GPU), a communication processor (CP), an image signal processor (ISP), or a controller. The processor 12 may be configured to control operation of the display module 11.

Data information desired for operation of the processor 12 or the display module 11 may be stored in the memory 13. When the processor 12 executes an application stored in the memory 13, an image data signal and/or an input control signal may be transferred to the display module 11, and the display module 11 may process the provided signal and may output image information through a display screen.

The power module 14 may include a power supply module such as a power adaptor or a battery device and a power conversion module that converts power supplied by the power supply module and generates power desired for operation of the electronic device EDE.

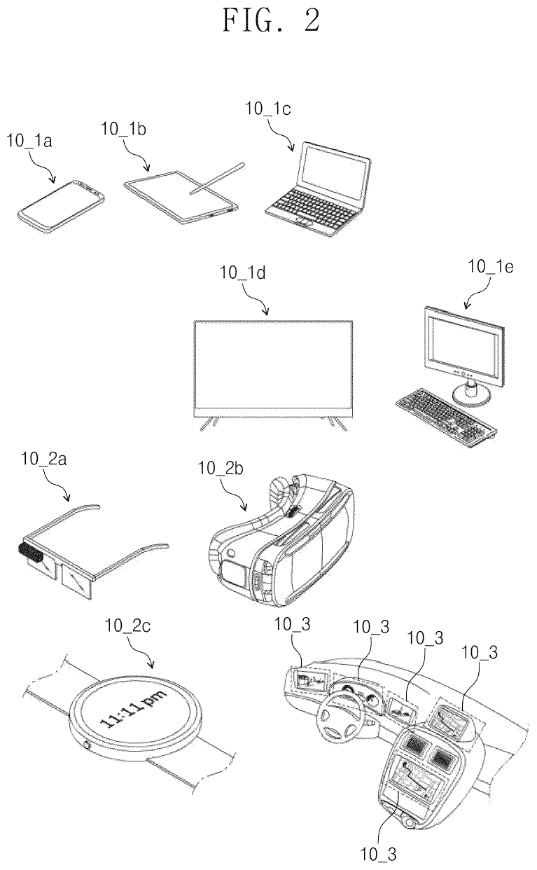

FIG. 2 illustrates schematic views of electronic devices according to various example embodiments.

Referring to FIG. 2, various electronic devices to which display devices according to some example embodiments are applied may include not only electronic devices for displaying images, such as a smart phone 10_1a, a tablet PC 10_1b, a laptop computer 10_1c, a TV 10_1d, and a desk monitor 10_1e, but also wearable electronic devices including a display module, such as smart glasses 10_2a, a head mounted display 10_2b, and a smart watch 10_2c, and vehicle electronic devices 10_3 including a display module, such as center information displays disposed on an instrument panel, a center fascia, and/or a dashboard of a vehicle and a room mirror display.

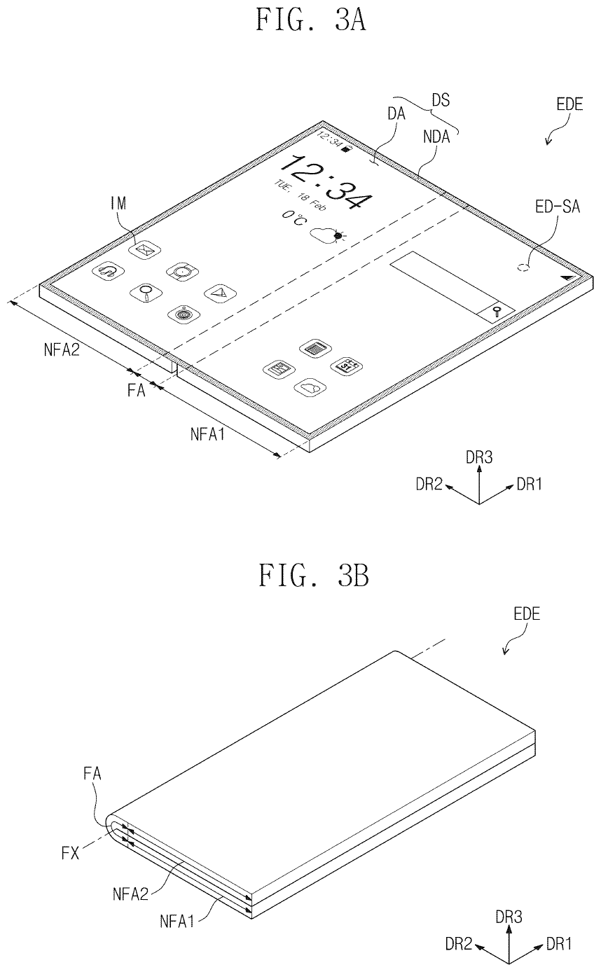

An example of some of the electronic devices according to the various example embodiments will be described in detail with reference to FIGS. 3A to 5.

FIGS. 3A and 3B are perspective views of an electronic device EDE according to an example embodiment of the present disclosure. FIG. 3A illustrates a flat state (e.g., an unfolded state) of the electronic device EDE, and FIG. 3B illustrates a folded state of the electronic device EDE.

Referring to FIGS. 3A and 3B, the electronic device EDE according to an example embodiment of the present disclosure may include a display surface DS defined by a first direction DR1 and a second direction DR2 crossing the first direction DR1. The electronic device EDE may provide an image IM to a user through the display surface DS.

The display surface DS may include a display area DA and a non-display area NDA around the display area DA. The display area DA may display the image IM, and the non-display area NDA may not display the image IM. The non-display area NDA may surround the display area DA. However, without being limited thereto, the shape of the display area DA and the shape of the non-display area NDA may be modified.

Hereinafter, a direction substantially perpendicular to a plane defined by the first direction DR1 and the second direction DR2 is defined as a third direction DR3. In addition, the expression “when viewed from above the plane” used herein may mean that it is viewed in the third direction DR3.

A sensor area ED-SA may be defined in the display area DA of the electronic device EDE. Although one sensor area ED-SA is illustrated as an example in FIG. 3A, the number of sensor areas ED-SA is not limited thereto. The sensor area ED-SA may be surrounded by the display area DA.

An electronic module may be disposed in an area overlapping the sensor area ED-SA. The electronic module may receive an external input transferred through the sensor area ED-SA or may provide an output through the sensor area ED-SA. For example, the electronic module may be, but is not particularly limited to, a camera module, a sensor that measures a distance, such as a proximity sensor, a sensor that recognizes a part of the user's body (e.g., fingerprint, iris, or face), or a small lamp that outputs light. Hereinafter, it will be provided as an example that the electronic module overlapping the sensor area ED-SA is a camera module.

The electronic device EDE may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The folding area FA may be referred to as a foldable area, and the first non-folding area NFA1 and the second non-folding area NFA2 may be referred to as a first non-foldable area and a second non-foldable area, respectively.

As illustrated in FIG. 3B, the folding area FA may be folded about a folding axis FX parallel to the first direction DR1. When the electronic device EDE is in the folded state, the folding area FA has a certain curvature and a certain radius of curvature. The first non-folding area NFA1 and the second non-folding area NFA2 may face each other, and the electronic device EDE may be folded in an inner-folding manner such that the display surface DS is not exposed to the outside.

In an example embodiment of the present disclosure, the electronic device EDE may be folded in an outer-folding manner such that the display surface DS is exposed to the outside. In an example embodiment of the present disclosure, the electronic device EDE may be folded in an inner-folding manner or an outer-folding manner in the unfolded state, but is not limited thereto. In an example embodiment of the present disclosure, the electronic device EDE may be configured to select one of an unfolding operation, an inner-folding operation, or an outer folding operation. In an example embodiment of the present disclosure, a plurality of folding axes may be defined in the electronic device EDE, and the electronic device EDE may be folded about each of the plurality of folding axes in an inner-folding manner or an outer-folding manner in the unfolded state.

Although the foldable electronic device EDE has been described as an example with reference to FIGS. 3A and 3B, the application of the present disclosure is not limited to the foldable electronic device EDE. For example, the present disclosure may also be applied to a rigid electronic device, for example, an electronic device that does not include the folding area FA.

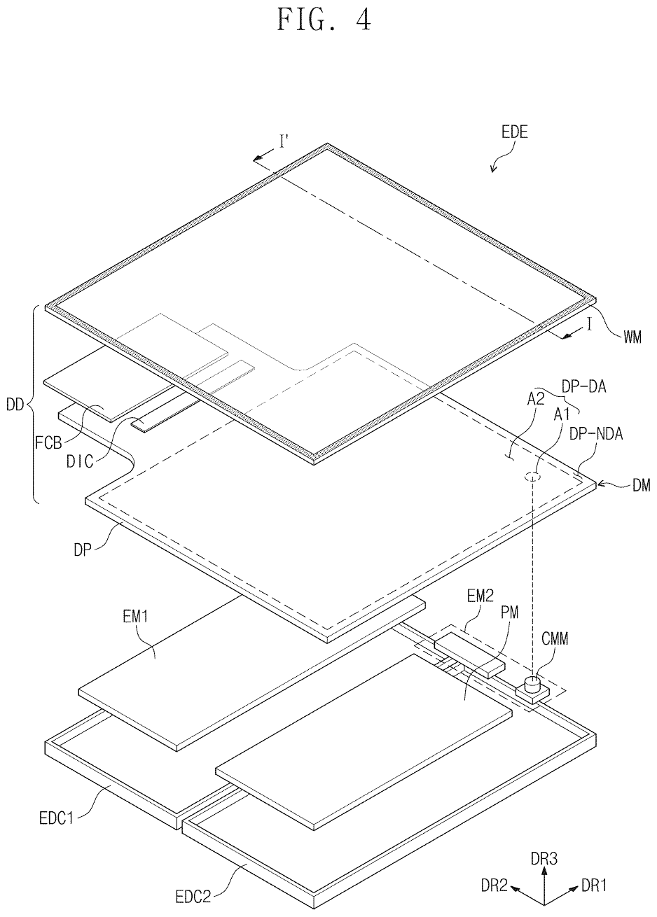

FIG. 4 is an exploded perspective view of an electronic device EDE according to an example embodiment of the present disclosure.

Referring to FIG. 4, the electronic device EDE may include a display device DD, a first electronic module EM1, a second electronic module EM2, a power supply module PM, and housings EDC1 and EDC2. The electronic device EDE may further include a mechanical structure for controlling a folding operation of the display device DD.

The display device DD includes a window module WM and a display module DM. The window module WM provides the front surface of the electronic device EDE. The display module DM may include at least a display panel DP. The display module DM generates an image and senses an external input.

In FIG. 4, the display module DM is illustrated as being the same as the display panel DP. However, the display module DM may substantially be a stack structure in which a plurality of components including the display panel DP are stacked one above another. Detailed description of the stack structure of the display module DM will be given below.

The display panel DP includes a display area DP-DA and a non-display area DP-NDA that correspond to the display area DA (refer to FIG. 3A) and the non-display area NDA (refer to FIG. 3A) of the electronic device EDE, respectively. The expression “one area/portion corresponds to another area/portion” used herein means that the one area/portion overlaps the other area/portion and is not limited to having the same area.

The display area DP-DA may include a first area A1 and a second area A2. The first area A1 may overlap or correspond to the sensor area ED-SA (refer to FIG. 3A) of the electronic device EDE. In this example embodiment, the first area A1 is illustrated in a circular shape. However, the first area A1 may have various shapes such as a polygonal shape, an oval shape, a shape having at least one curved side, or an irregular shape and is not limited to any one example embodiment. The first area A1 may be referred to as a component area, and the second area A2 may be referred to as a main display area or a general display area.

The first area A1 may have a higher transmittance than the second area A2. The first area A1 may overlap a camera module CMM to be described below.

The display module DM may further include a driver chip DIC disposed on the non-display area DP-NDA. The display module DM may further include a flexible circuit film FCB coupled to the non-display area DP-NDA.

The driver chip DIC may include driving elements for driving pixels of the display panel DP, for example, a data driver circuit. Although FIG. 4 illustrates the structure in which the driver chip DIC is mounted on the display panel DP, example embodiments of the present disclosure are not limited thereto. For example, the driver chip DIC may be mounted on the flexible circuit film FCB.

The power supply module PM supplies power desired for overall operation of the electronic device EDE. The power supply module PM may include a conventional battery module.

The first electronic module EM1 and the second electronic module EM2 include various functional modules for operating the electronic device EDE. Each of the first electronic module EM1 and the second electronic module EM2 may be directly mounted on a mother board electrically connected with the display panel DP or may be mounted on a separate substrate and electrically connected to the mother board through a connector (not illustrated).

The second electronic module EM2 may include the camera module CMM, a light emitting module, and/or a light receiving module. The camera module CMM may take a still image and a moving image. A plurality of camera modules CMM may be provided. Some of the camera modules CMM may overlap the first area A1. An external input (e.g., light) may be provided to the camera module CMM through the first area A1. For example, the camera module CMM may take an external image by receiving natural light through the first area A1.

The housings EDC1 and EDC2 accommodate the display module DM, the first electronic module EM1, the second electronic module EM2, and the power supply module PM. The housings EDC1 and EDC2 protect the components accommodated in the housings EDC1 and EDC2, such as the display module DM, the first electronic module EM1, the second electronic module EM2, and the power supply module PM. Although two housings EDC1 and EDC2 separated from each other are illustrated as an example in FIG. 4, example embodiments of the present disclosure are not limited thereto. Although not illustrated, the electronic device EDE may further include a hinge structure for connecting the two housings EDC1 and EDC2. The housings EDC1 and EDC2 may be coupled with the window module WM.

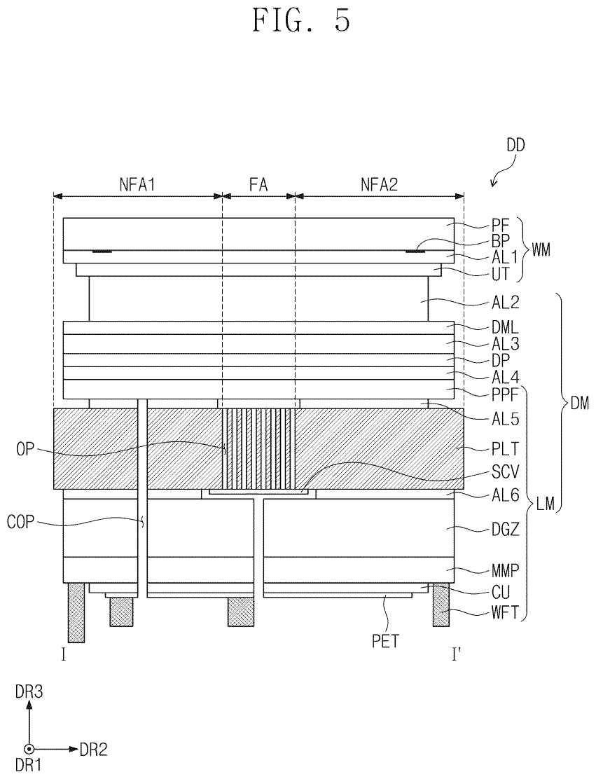

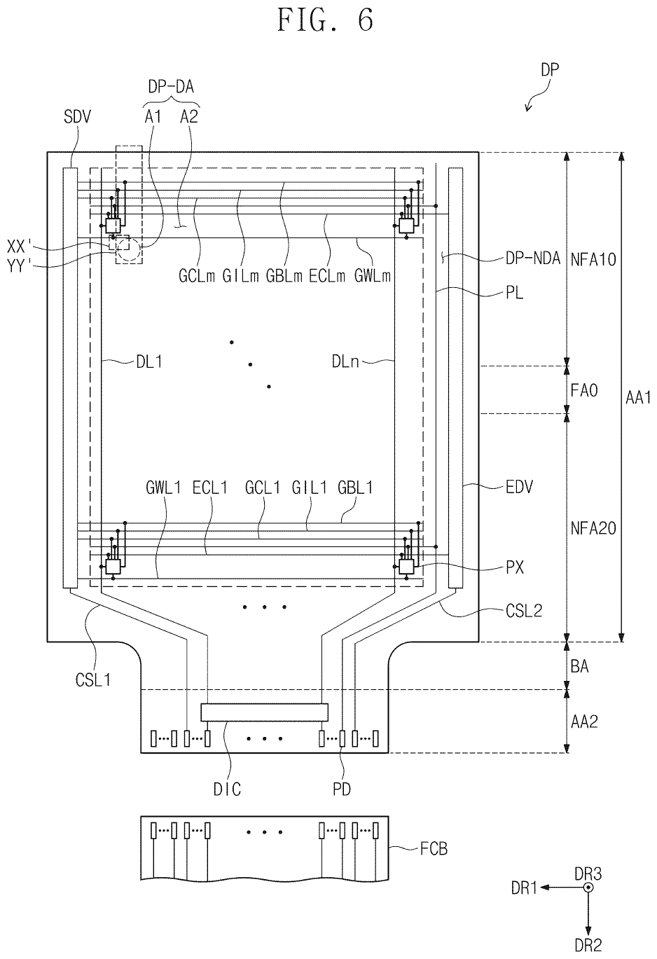

FIG. 5 is a sectional view of a display device DD according to an example embodiment of the present disclosure. FIG. 5 is a sectional view of the display device DD taken along line I-I′ of FIG. 4 according to an embodiment of the present disclosure.

Referring to FIG. 5, the display device DD may include the window module WM and the display module DM.

The window module WM may include a window UT, a protective film PF disposed on the window UT, and a bezel pattern BP.

The window UT may be chemically strengthened glass. As the window UT is applied to the display device DD, a crease or wrinkle may be reduced or minimized even though folding and unfolding operations are repeated.

The protective film PF may include polyimide, polycarbonate, polyamide, triacetylcellulose, polymethylmethacrylate, or polyethylene terephthalate. Although not separately illustrated, at least one of a hard coating layer, an anti-fingerprint layer, or an anti-reflective layer may be disposed on the upper surface of the protective film PF.

The bezel pattern BP overlaps the non-display area NDA (refer to FIG. 3A). The bezel pattern BP may be disposed on one surface of the window UT or one surface of the protective film PF. In FIG. 5, the bezel pattern BP disposed on the lower surface of the protective film PF is illustrated as an example. Without being limited thereto, the bezel pattern BP may be disposed on the upper surface of the protective film PF, the upper surface of the window UT, or the lower surface of the window UT. The bezel pattern BP may be a colored light-blocking film and may be formed, for example, by a coating method. The bezel pattern BP may include a base material and a dye or pigment mixed in the base material. The bezel pattern BP may have a closed-line shape when viewed from above the plane.

A first adhesive layer AL1 may be disposed between the protective film PF and the window UT. The first adhesive layer AL1 may be a pressure sensitive adhesive (PSA) film or an optically clear adhesive (OCA) member. Adhesive layers to be described below may also be the same as the first adhesive layer AL1 and may include a conventional adhesive.

The first adhesive layer AL1 may have a thickness sufficient to cover the bezel pattern BP. For example, the bezel pattern BP may have a thickness of about 3 to 8 micrometers, and the first adhesive layer AL1 may have a thickness that does not cause bubbles around the bezel pattern BP.

The first adhesive layer AL1 may be separated from the window UT. Because the strength of the protective film PF is lower than that of the window UT, the protective film PF may be relatively easily scratched. The first adhesive layer AL1 and the damaged protective film PF may be separated from the window UT, and thereafter a new protective film PF may be attached to the window UT.

The display module DM may include an impact absorbing layer DML, the display panel DP, and a lower member LM.

The impact absorbing layer DML may be disposed on the display panel DP. The impact absorbing layer DML may be a functional layer for protecting the display panel DP from external impact. The impact absorbing layer DML may be coupled to the window UT through a second adhesive layer AL2 and may be coupled to the display panel DP through a third adhesive layer AL3.

The lower member LM may be disposed under the display panel DP. The lower member LM may include a panel protection layer PPF, a support layer PLT, a cover layer SCV, a digitizer DGZ, shielding layers MMP, heat radiating layers CU, protective layers PET, and waterproof tapes WFT. In an example embodiment of the present disclosure, the lower member LM may not include some of the aforementioned components or may further include other components. In addition, the stacking sequence illustrated in FIG. 5 is illustrative, and the stacking sequence of the components may be changed.

The panel protection layer PPF may be disposed under the display panel DP. The panel protection layer PPF may be attached to the rear surface of the display panel DP through a fourth adhesive layer AL4. The panel protection layer PPF may protect the bottom of the display panel DP. The panel protection layer PPF may include a flexible plastic material. The panel protection layer PPF may reduce or prevent a scratch on the rear surface of the display panel DP in a manufacturing process of the display panel DP. The panel protection layer PPF may be a colored polyimide film. For example, the panel protection film PPF may be an opaque yellow film, but is not limited thereto.

The support layer PLT is disposed under the panel protection layer PPF. The support layer PLT supports the components disposed on the upper side of the support layer PLT and maintains the unfolded state and the folded state of the display device DD. In an example embodiment of the present disclosure, the support layer PLT may include at least a first support portion corresponding to the first non-folding area NFA1, a second support portion corresponding to the second non-folding area NFA2, and a folding portion corresponding to the folding area FA. The first support portion and the second support portion may be spaced apart from each other in the second direction DR2. The folding portion may be disposed between the first support portion and the second support portion, and a plurality of openings OP may be defined in the folding portion. The flexibility of a portion of the support layer PLT may be improved by the openings OP. The flexibility of the portion of the support layer PLT that overlaps the folding area FA may be improved by the openings OP.

The support layer PLT may include carbon fiber reinforced plastic (CFRP), but is not particularly limited thereto. In some example embodiments, the first support portion and the second support portion may include a non-metallic material, plastic, glass fiber reinforced plastic, or glass. The plastic may include polyimide, polyethylene, or polyethylene terephthalate, but is not particularly limited thereto. The first support portion and the second support portion may include the same material. The folding portion may include the same material as the first support portion and the second support portion or may include a material different from the material of the first support portion and the second support portion. For example, the folding portion may include a material having an elastic modulus of about 60 GPa or more and may include a metallic material such as stainless steel. For example, the folding portion may include SUS 304 (i.e., 304 stainless steel according to the Japanese Industrial Standard (JIS) designation and equivalent to the American Iron and Steel Institute (AISI) or ASTM 304 stainless steel). However, without being limited thereto, the folding portion may include various metallic materials.

The support layer PLT may be attached to the panel protection layer PPF through a fifth adhesive layer AL5. A plurality of fifth adhesive layers AL5 may be provided. The fifth adhesive layers AL5 may be spaced apart from each other with the folding area FA therebetween. The fifth adhesive layer AL5 may not overlap the plurality of openings OP. In addition, the fifth adhesive layer AL5 may be spaced apart from the plurality of openings OP when viewed from above the plane. Because the fifth adhesive layers AL5 is not disposed in the area corresponding to the folding area FA, the flexibility of the support layer PLT may be improved.

In the area overlapping the folding area FA, the panel protection layer PPF may be spaced apart from the support layer PLT. That is, in the portion overlapping the folding area FA, an empty space may be defined between the support layer PLT and the panel protection layer PPF. Because the empty space is defined between the panel protection layer PPF and the support layer PLT, the shape of the plurality of openings OP defined in the support layer PPT may not be visible from outside the electronic device EDE (refer to FIG. 3A).

The fifth adhesive layer AL5 may have a smaller thickness than the fourth adhesive layer AL4. For example, the fourth adhesive layer AL4 may have a thickness of about 25 micrometers, and the fifth adhesive layer AL5 may have a thickness of about 16 micrometers. As the thickness of the fifth adhesive layer AL5 is decreased, a step caused by the fifth adhesive layer AL5 may be decreased. As the step is decreased, the deformation of the stack structure due to folding and unfolding operations of the electronic device EDE (refer to FIG. 3A) may be reduced. However, the plurality of openings OP may be visible, or the fifth adhesive layer AL5 may be detached due to repeated folding operations. As the thickness of the fifth adhesive layer AL5 is increased, the plurality of openings OP may not be visible, and the reliability of the adhesive force of the fifth adhesive layer AL5 may be improved by the repeated folding operations. However, the step may be enlarged. Accordingly, the thickness of the fifth adhesive layer AL5 may be selected in an appropriate range in consideration of folding reliability, adhesive reliability, and/or visibility of the plurality of openings OP.

The cover layer SCV may be disposed under the support layer PLT. The cover layer SCV may be coupled to the support layer PLT by an adhesive member. The cover layer SCV may cover the plurality of openings OP defined in the support layer PLT. Accordingly, the cover layer SCV may reduce or prevent infiltration of foreign matter into the plurality of openings OP. The cover layer SCV may have a lower elastic modulus than the support layer PLT. For example, the cover layer SCV may include thermoplastic polyurethane, rubber, or silicone, but is not limited thereto.

The digitizer DGZ may be disposed under the support layer PLT. A plurality of digitizers DGZ may be provided. For example, the plurality of digitizers DGZ may be spaced apart from each other in the second direction DR2. A portion of each of the plurality of digitizers DGZ may overlap the non-folding area NFA1 or NFA2, and the remaining portion may overlap the folding area FA. A portion of each of the plurality of digitizers DGZ may overlap some of the plurality of openings OP when viewed from above the plane.

Each of the plurality of digitizers DGZ may include a plurality of loop coils that generate a magnetic field having a desired (or alternatively, preset) resonant frequency with an input device (hereinafter, referred to as a pen). The plurality of digitizers DGZ may be referred to as an electromagnetic radiation (EMR) sensing panel.

A magnetic field formed by the plurality of digitizers DGZ is applied to an LC resonance circuit of the pen that includes an inductor (e.g., a coil) and a capacitor. The coil generates a current by the received magnetic field and transfers the generated current to the capacitor. Accordingly, the capacitor charges the current input from the coil and discharges the charged current to the coil. Eventually, a magnetic field having a resonant frequency is emitted from the coil. The magnetic field emitted by the pen may be reabsorbed by the loop coils of the plurality of digitizers DGZ, and thus it is possible to determine which position of the plurality of digitizers DGZ the pen is close to.

The shielding layers MMP may be disposed under the plurality of digitizers DGZ, respectively. Each of the shielding layers MMP may include magnetic metal powder. The shielding layers MMP may be referred to as magnetic metal powder layers, magnetic layers, magnetic circuit layers, or magnetic path layers. The shielding layers MMP may shield a magnetic field.

The heat radiating layers CU may be disposed under the shielding layers MMP, respectively. The heat radiating layers CU may be sheets having relatively high thermal conductivity. For example, each of the heat radiating layers CU may include graphite, copper, or a copper alloy, but is not particularly limited thereto.

In an example embodiment of the present disclosure, the digitizers DGZ and the shielding layers MMP may be omitted. In this case, the heat radiating layers CU may be coupled to the bottom of the support layer PLT.

The protective layers PET may be disposed under the heat radiating layers CU, respectively. The protective layers PET may be insulating layers. For example, the protective layers PET may be layers provided to reduce or prevent the inflow of static electricity. Accordingly, electrical interference between the flexible circuit film FCB (refer to FIG. 4) and the members disposed on the protective layers PET may be reduced or prevented by the protective layers PET.

The waterproof tapes WFT may be attached to the shielding layers MMP and the protective layers PET. The waterproof tapes WFT may be attached to a set bracket (not illustrated). The thickness of a waterproof tape attached to the shielding layers MMP among the waterproof tapes WFT may be different from the thickness of a waterproof tape attached to the protective layers PET among the waterproof tapes WFT.

A through-hole COP may be defined in at least some of the components constituting the lower member LM. The through-hole COP may overlap or correspond to the sensor area ED-SA (refer to FIG. 3A) of the electronic device EDE. At least a portion of the camera module CMM (refer to FIG. 4) may be inserted into the through-hole COP.

Although FIG. 5 illustrates an example that the through-hole COP is provided from the rear surface of one of the protective layers PET to the fifth adhesive layer AL5, example embodiments of the present disclosure are not limited thereto. For example, the through-hole COP may be provided from the rear surface of the one protective layer to the upper surface of the panel protection layer PPF or from the rear surface of the one protective layer to the upper surface of the fourth adhesive layer AL4.

FIG. 6 is a plan view of a display panel DP according to an example embodiment of the present disclosure.

Referring to FIG. 6, the display area DP-DA and the non-display area DP-NDA around the display area DP-DA may be defined in the display panel DP. The display area DP-DA and the non-display area DP-NDA may be distinguished from each other by the presence or absence of pixels PX. The pixels PX are disposed in the display area DP-DA. A scan driver SDV, a data driver, and an emission driver EDV may be disposed in the non-display area DP-NDA. The data driver may be a circuit configured in the driver chip DIC.

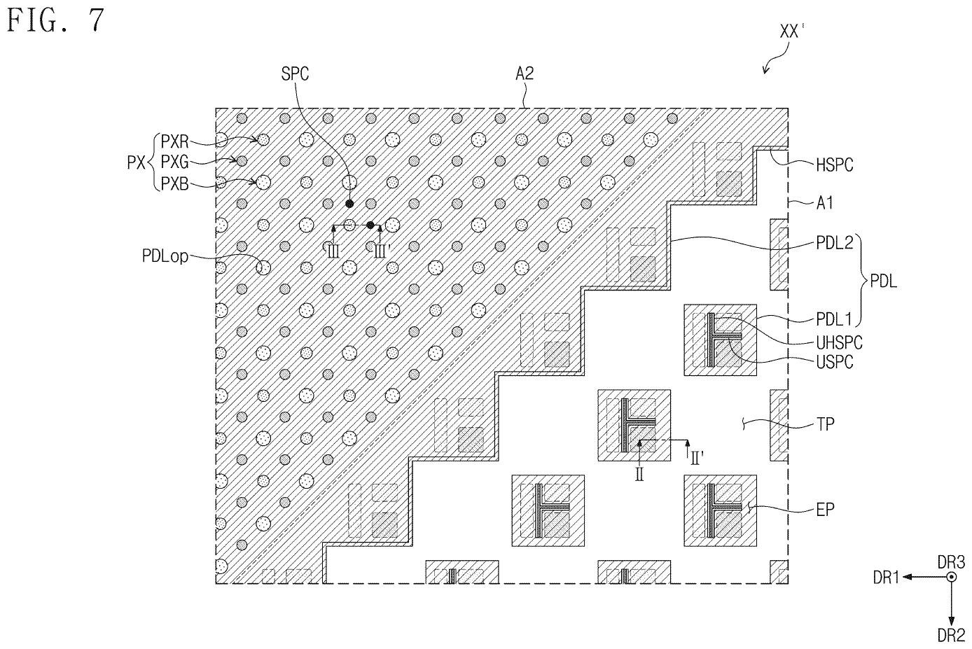

The display area DP-DA may include the first area A1 and the second area A2. The first area A1 and the second area A2 may be distinguished from each other by the presence or absence of a transmissive area TP (refer to FIG. 7). Detailed description of the first area A1 and the second area A2 will be given below.

The display panel DP may include a first panel area AA1, a bending area BA, and a second panel area AA2 defined in the second direction DR2. The second panel area AA2 and the bending area BA may be partial areas of the non-display area DP-NDA. The bending area BA is disposed between the first panel area AA1 and the second panel area AA2.

The first panel area AA1 is an area corresponding to the display surface DS of FIG. 3A. The first panel area AA1 may include a first non-folding area NFA10, a second non-folding area NFA20, and a folding area FA0. The first non-folding area NFA10, the second non-folding area NFA20, and the folding area FA0 correspond to the first non-folding area NFA1, the second non-folding area NFA2, and the folding area FA of FIGS. 3A and 3B, respectively.

The width of the bending area BA and the width (or, length) of the second panel area AA2 in the first direction DR1 may be smaller than the width (or, length) of the first panel area AA1 in the first direction DR1. An area having a short length in the direction of a bending axis may be more easily bent.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, a first control line CSL1, a second control line CSL2, a driving voltage line PL, and a plurality of pads PD. Here, m and n are natural numbers of 2 or more.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driver SDV. The data lines DL1 to DLm may extend in the second direction DR2 and may be electrically connected to the driver chip DIC via the bending area BA. The emission control lines ECL1 to ECLm may extend in the first direction DR1 and may be electrically connected to the emission driver EDV.

The driving voltage line PL may include a portion extending in the first direction DR1 and a portion extending in the second direction DR2. The portion extending in the first direction DR1 and the portion extending in the second direction DR2 may be disposed on different layers. The portion of the driving voltage line PL that extends in the second direction DR2 may extend to the second panel area AA2 via the bending area BA. The driving voltage line PL may provide a driving voltage to the pixels PX.

The first control line CSL1 may be connected to the scan driver SDV and may extend toward the lower end of the second panel area AA2 via the bending area BA. The second control line CSL2 may be connected to the emission driver EDV and may extend toward the lower end of the second panel area AA2 via the bending area BA.

The pads PD may be disposed adjacent to the lower end of the second panel area AA2 when viewed from above the plane. The driver chip DIC, the driving voltage line PL, the first control line CSL1, and the second control line CSL2 may be electrically connected to the pads PD. The flexible circuit film FCB may be electrically connected to the pads PD through an anisotropic conductive adhesive layer.

FIG. 7 is an enlarged plan view of a partial area of a display panel DP according to an example embodiment of the present disclosure. FIG. 7 is an enlarged plan view of area XX′ illustrated in FIG. 6.

Referring to FIGS. 6 and 7, the display panel DP may include the first area A1 and the second area A2.

A plurality of pixels PX may be provided. The plurality of pixels PX may include first pixels PXR, second pixels PXG, and third pixels PXB. The first pixels PXR may be red light emitting pixels, the second pixels PXG may be green light emitting pixels, and the third pixels PXB may be blue light emitting pixels.

In an example embodiment of the present disclosure, the first pixels PXR, the second pixels PXG, and the third pixels PXB may be disposed in the second area A2. The planar shape of each of the first pixels PXR, the second pixels PXG, and the third pixels PXB illustrated in FIG. 7 may correspond to the shape of an emissive area defined in a light emitting element. The emissive area may be an area defined by a pixel defining opening defined in a pixel defining layer PDL. The pixels PX may not be disposed in the first area A1.

In FIG. 7, the pixel defining layer PDL is illustrated. The pixel defining layer PDL may include a first pixel defining layer PDL1 and a second pixel defining layer PDL2.

The first pixel defining layer PDL1 may be disposed in the first area A1. The first area A1 may include transmissive areas TP and a light blocking area EP, and the first pixel defining layer PDL1 may not overlap the transmissive areas TP and may overlap the light blocking area EP. In the light blocking area EP, a pixel circuit to be described may be disposed, but a light emitting element may not be disposed. Accordingly, the light blocking area EP may be referred to as a dummy area, a non-emissive area, or an element area.

In an example embodiment of the present disclosure, a plurality of first pixel defining layers PDL1 may be provided. The plurality of first pixel defining layers PDL1 may be spaced apart from one another in the first area A1. However, this is only an example, and example embodiments of the present disclosure are not limited thereto. For example, the first pixel defining layer PDL1 may have an interconnected structure in the first area A1, like a division layer 310 illustrated in FIG. 9.

The second pixel defining layer PDL2 may cover the second area A2 and a portion of the first area A1. For example, pixel defining openings PDLop that correspond to the first pixels PXR, the second pixels PXG, and the third pixels PXB in a one-to-one manner may be defined in the second pixel defining layer PDL2.

In FIG. 7, a first spacer HSPC, a first protruding spacer SPC, a second spacer UHSPC, and a second protruding spacer USPC are illustrated.

The first spacer HSPC may be disposed on the second pixel defining layer PDL2. The first spacer HSPC may cover the second area A2 and a portion of the first area A1 in the same manner as the second pixel defining layer PDL2. The first protruding spacer SPC may be disposed on the first spacer HSPC. The first protruding spacer SPC may have a circular shape when viewed from above the plane. The first protruding spacer SPC may be disposed in the second area A2.

The height (or, thickness) of the first protruding spacer SPC may be greater than the height (or, thickness) of the first spacer HSPC. The height of the first spacer HSPC may range from about 0.1 to 0.5 μm, and the total height of the first spacer HSPC and the first protruding spacer SPC may range from about 1.1 to 2.0 μm. However, the height of the first spacer HSPC and the total height of the first spacer HSPC and the first protruding spacer SPC are not limited to the examples described above.

The second spacer UHSPC may be disposed on the first pixel defining layer PDL1. The second protruding spacer USPC may be disposed on the second spacer UHSPC. When viewed from above the plane, the second spacer UHSPC may have a larger area than the second protruding spacer USPC.

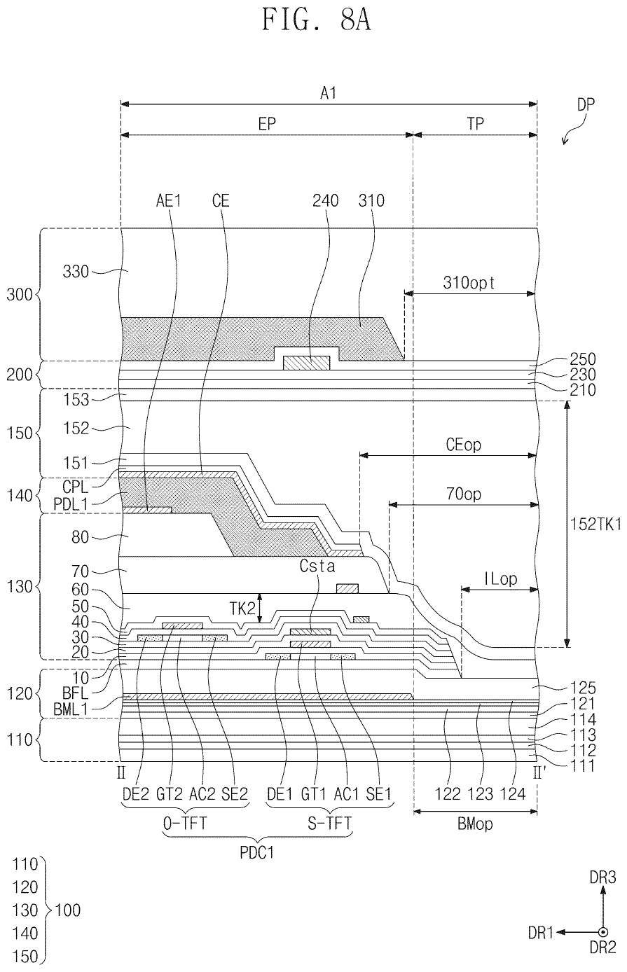

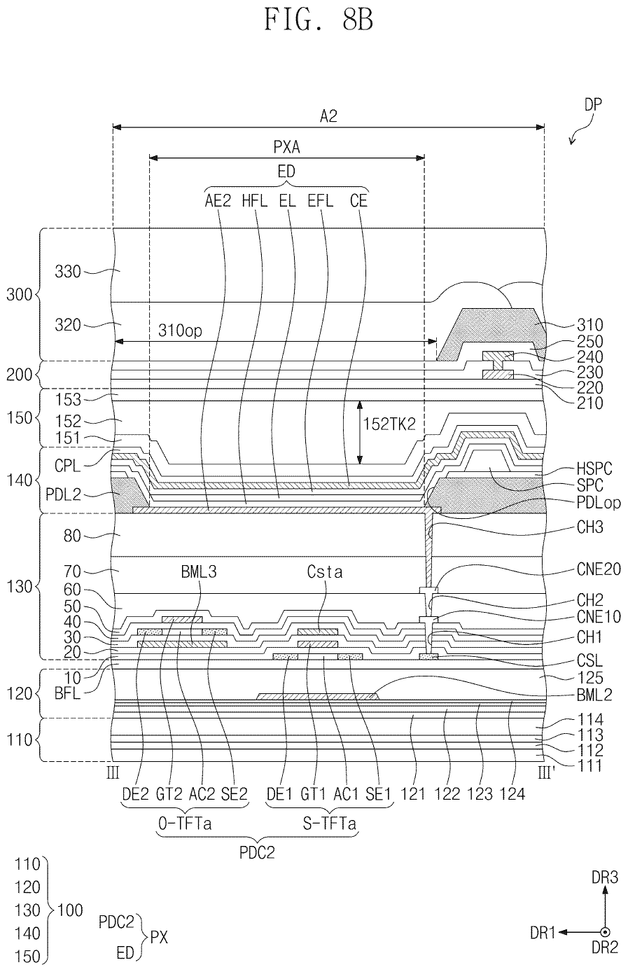

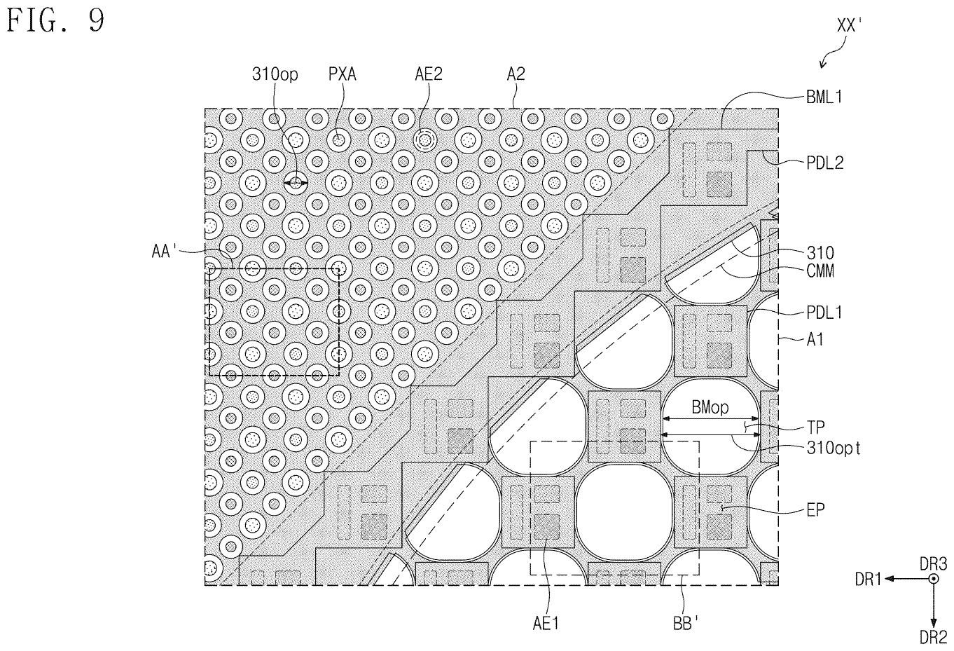

FIG. 8A is a sectional view illustrating the first area A1 of the display panel DP according to an example embodiment of the present disclosure. FIG. 8B is a sectional view illustrating the second area A2 of the display panel DP according to an example embodiment of the present disclosure. FIG. 8A illustrates a cross-section corresponding to cutting line II-II′ of FIG. 7, and FIG. 8B illustrates a cross-section corresponding to cutting line III-III′ of FIG. 7.

Referring to FIGS. 8A and 8B, the display panel DP may include a display layer 100, a sensor layer 200, and an anti-reflective layer 300. The display layer 100 may include a base layer 110, a barrier layer 120, a circuit layer 130, an element layer 140, and an encapsulation layer 150.

The base layer 110 may include first to fourth sub-base layers 111, 112, 113, and 114.

Each of the first sub-base layer 111 and the fourth sub-base layer 114 may include at least one of a polyimide resin, an acrylic resin, a methacrylic resin, a polyisoprene resin, a vinyl resin, an epoxy resin, a urethane-based resin, a celluosic resin, a siloxane-based resin, a polyamide resin, or a perylene-based resin. Meanwhile, in this specification, a “~~”—based resin means a resin including a “~~” functional group. For example, each of the first sub-base layer 111 and the fourth sub-base layer 114 may include polyimide.

Each of the second sub-base layer 112 and the third sub-base layer 113 may include an inorganic material. For example, each of the second sub-base layer 112 and the third sub-base layer 113 may include at least one of silicon oxide, silicon nitride, silicon oxy nitride, or amorphous silicon. For example, the second sub-base layer 112 may include silicon oxy nitride, and the third sub-base layer 113 may include silicon oxide.

The barrier layer 120 may be disposed on the base layer 110. The barrier layer 120 may include a plurality of sub-barrier layers 121, 122, 123, 124, and 125, a first lower light blocking layer BML1, and a second lower light blocking layer BML2.

The first lower light blocking layer BML1 may be referred to as a first lower layer, a first lower metal layer, a first lower electrode layer, a first lower shielding layer, a first light blocking layer, a first metal layer, a first electrode layer, a first shielding layer, or a first overlap layer, and the second lower light blocking layer BML2 may be referred to as a second lower layer, a second lower metal layer, a second lower electrode layer, a second lower shielding layer, a second light blocking layer, a second metal layer, a second electrode layer, a second shielding layer, or a second overlap layer.

The plurality of sub-barrier layers 121, 122, 123, 124, and 125 may include the first sub-barrier layer 121, the second sub-barrier layer 122, the third sub-barrier layer 123, the fourth sub-barrier layer 124, and the fifth sub-barrier layer 125 sequentially stacked in a direction away from the base layer 110. Each of the first to fifth sub-barrier layers 121, 122, 123, 124, and 125 may include an inorganic material. For example, each of the first to fifth sub-barrier layers 121, 122, 123, 124, and 125 may include at least one of silicon oxide, silicon nitride, silicon oxy nitride, or amorphous silicon. For example, the first sub-barrier layer 121 may include silicon oxy nitride, the second sub-barrier layer 122 may include silicon oxide, the third sub-barrier layer 123 may include amorphous silicon, the fourth sub-barrier layer 124 may include silicon oxide, and the fifth sub-barrier layer 125 may include silicon oxide.

The first lower light blocking layer BML1 may be disposed in the first area A1, and the second lower light blocking layer BML2 may be disposed in the second area A2. The first lower light blocking layer BML1 and the second lower light blocking layer BML2 may be electrically insulated from each other, and different signals may be applied to the first lower light blocking layer BML1 and the second lower light blocking layer BML2. For example, a constant voltage having a certain voltage level may be applied to the first lower light blocking layer BML1, and a driving voltage provided to a second pixel circuit PDC2 may be provided to the second lower light blocking layer BML2.

The first lower light blocking layer BML1 and the second lower light blocking layer BML2 may be disposed on the same layer and may include the same material. For example, the first lower light blocking layer BML1 and the second lower light blocking layer BML2 may be disposed between the fourth sub-barrier layer 124 and the fifth sub-barrier layer 125. The first lower light blocking layer BML1 and the second lower light blocking layer BML2 may be covered by the fifth sub-barrier layer 125. Because the fifth sub-barrier layer 125 among the first to fifth sub-barrier layers 121, 122, 123, 124, and 125 has the greatest thickness, the degree to which the characteristics of transistors are changed by the voltages provided to the first lower light blocking layer BML1 and the second lower light blocking layers BML2 may be reduced.

The first lower light blocking layer BML1 may have a first opening BMop that defines the transmissive area TP. The first lower light blocking layer BML1 may be a pattern that functions as a mask when an electrode opening CEop is formed in a common electrode CE. For example, light emitted toward the common electrode CE from the rear surface of the base layer 110 may pass through the first opening BMop of the first lower light blocking layer BML1 and may reach a portion of the common electrode CE and a portion of a capping layer CPL. That is, a portion of the common electrode CE and a portion of the capping layer CPL may be removed by light passing through the first opening BMop of the first lower light blocking layer BML1. The light may be a laser beam.

In the first area A1, the area overlapping the first opening BMop of the first lower light blocking layer BML1 may be defined as the transmissive area TP, and the remaining area may be defined as the light blocking area EP. A first pixel electrode AE1 may be disposed in the light blocking area EP. The first pixel electrode AE1 may be spaced apart from the transmissive area TP.

A buffer layer BFL may be disposed on the barrier layer 120. The buffer layer BFL may be provided in both the first area A1 and the second area A2. The buffer layer BFL may reduce or prevent metal atoms or impurities from diffusing from the base layer 110 to a first semiconductor pattern. In addition, the buffer layer BFL may adjust the rate at which heat is provided during a crystallization process for forming the first semiconductor pattern, thereby enabling the first semiconductor pattern to be more uniformly formed.

The buffer layer BFL may include a plurality of inorganic layers. For example, the buffer layer BFL may include a first sub-buffer layer including silicon nitride and a second sub-buffer layer that is disposed on the first sub-buffer layer and that includes silicon oxide. The buffer layer BFL may not overlap the transmissive area TP. That is, an opening corresponding to the transmissive area TP may be defined in the buffer layer BFL. Because the buffer layer BFL is not provided in the transmissive area TP, the transmittance of the transmissive area TP may be further improved.

A first pixel circuit PDC1 disposed in the first area A1 and a pixel PX disposed in the second area A2 are illustrated in FIGS. 8A and 8B, respectively. The pixel PX may include a light emitting element ED and the second pixel circuit PDC2.

The circuit layer 130 may be disposed on the buffer layer BFL, and the element layer 140 may be disposed on the circuit layer 130. A sectional view of the first pixel electrode AE1, the common electrode CE, and a portion of the first pixel circuit PDC1 disposed in the first area A1 is illustrated in FIG. 8A, and a sectional view of the light emitting element ED and a portion of the second pixel circuit PDC2 disposed in the second area A2 is illustrated in FIG. 8B.

Referring to FIG. 8A, a silicon thin film transistor S-TFT and an oxide thin film transistor O-TFT of the first pixel circuit PDC1 are illustrated as an example. Referring to FIG. 8B, a silicon thin film transistor S-TFTa and an oxide thin film transistor O-TFTa of the second pixel circuit PDC2 are illustrated as an example. In the second area A2, the second lower light blocking layer BML2 may overlap some of the transistors and may not overlap the other transistors. For example, the second lower light blocking layer BML2 may overlap a portion of the area where the second pixel circuit PDC2 is disposed, and the voltage provided to the second lower light blocking layer BML2 may be provided in synchronization with operation of the second pixel circuit PDC2.

Referring to FIGS. 8A and 8B, the first semiconductor pattern may be disposed on the buffer layer BFL. The first semiconductor pattern may include a silicon semiconductor. For example, the silicon semiconductor may include amorphous silicon or polycrystalline silicon. For example, the first semiconductor pattern may include low-temperature polycrystalline silicon.

FIGS. 8A and 8B illustrate only a portion of the semiconductor pattern disposed on the buffer layer BFL, and the first semiconductor pattern may be further disposed in other areas. The first semiconductor pattern may be arranged across pixels according to a specific rule. The first semiconductor pattern may have different electrical properties depending on whether doping is performed or not. The first semiconductor pattern may include a first area having relatively high conductivity and a second area having relatively low conductivity. The first area may be doped with an N-type dopant or a P-type dopant. A P-type transistor may include a doped area doped with a P-type dopant, and an N-type transistor may include a doped area doped with an N-type dopant. The second area may be a non-doped area or may be an area more lightly doped than the first area.

The first area may have a higher conductivity than the second area and may substantially serve as an electrode or a signal line. The second area may substantially correspond to an active area (or, a channel) of a transistor. In other words, one portion of the first semiconductor pattern may be the active area of the transistor, another portion may be a source or drain of the transistor, and the rest portion may be a connecting electrode or a connecting signal line.

A source area SE1, an active area AC1, and a drain area DE1 of the silicon thin film transistor S-TFT or S-TFTa may be formed from the first semiconductor pattern. The source area SE1 and the drain area DE1 may extend from the active area AC1 in opposite directions, respectively, on the cross-section.

In FIG. 8B, a portion of a connecting signal line CSL formed from the first semiconductor pattern is illustrated.

The circuit layer 130 may include a plurality of inorganic layers and a plurality of organic layers. In an example embodiment, first to fifth insulating layers 10, 20, 30, 40, and 50 sequentially stacked on the buffer layer BFL may be inorganic layers, and sixth to eighth insulating layers 60, 70, and 80 may be organic layers.

The first insulating layer 10 may be disposed on the buffer layer BFL. The first insulating layer 10 may cover the first semiconductor pattern. The first insulating layer 10 may be an inorganic layer and/or an organic layer and may have a single-layer structure or a multi-layer structure. The first insulating layer 10 may include at least one of aluminum oxide, titanium oxide, silicon oxide, silicon nitride, silicon oxy nitride, zirconium oxide, or hafnium oxide. In this example embodiment, the first insulating layer 10 may be a single silicon oxide layer. Not only the first insulating layer 10 but also the other insulating layers of the circuit layer 130 to be described below may have a single-layer structure or a multi-layer structure.

A gate electrode GT1 of the silicon thin film transistor S-TFT or S-TFTa is disposed on the first insulating layer 10. The gate electrode GT1 may be a portion of a metal pattern. The gate electrode GT1 overlaps the active area AC1. The gate electrode GT1 may function as a mask in a process of doping the first semiconductor pattern. The gate electrode GT1 may include titanium, silver, an alloy containing silver, molybdenum, an alloy containing molybdenum, aluminum, an alloy containing aluminum, aluminum nitride, tungsten, tungsten nitride, copper, indium tin oxide, or indium zinc oxide, but is not particularly limited thereto.

The second insulating layer 20 may be disposed on the first insulating layer 10 and may cover the gate electrode GT1. The second insulating layer 20 may be an inorganic layer and may have a single-layer structure or a multi-layer structure. The second insulating layer 20 may include at least one of silicon oxide, silicon nitride, or silicon oxy nitride. In this example embodiment, the second insulating layer 20 may have a single-layer structure including a silicon nitride layer.

The third insulating layer 30 may be disposed on the second insulting layer 20. The third insulating layer 30 may be an inorganic layer and may have a single-layer structure or a multi-layer structure. For example, the third insulating layer 30 may have a multi-layer structure including a silicon oxide layer and a silicon nitride layer. One electrode Csta of a capacitor may be disposed between the second insulating layer 20 and the third insulating layer 30. In addition, the other electrode of the capacitor may be disposed between the first insulating layer 10 and the second insulating layer 20.

A second semiconductor pattern may be disposed on the third insulating layer 30. The second semiconductor pattern may include an oxide semiconductor. The oxide semiconductor may include a plurality of areas distinguished from one another depending on whether metal oxide is reduced or not. The area where the metal oxide is reduced (hereinafter, referred to as the reduced area) has a higher conductivity than the area where the metal oxide is not reduced (hereinafter, referred to as the non-reduced area). The reduced area substantially serves as a source or drain of a transistor or a signal line. The non-reduced area substantially corresponds to an active area (or a semiconductor area or a channel) of the transistor. In other words, one portion of the second semiconductor pattern may be the active area of the transistor, another portion may be the source or drain area of the transistor, and the rest portion may be a signal transmission area.

A source area SE2, an active area AC2, and a drain area DE2 of the oxide thin film transistor O-TFT or O-TFTa may be formed from the second semiconductor pattern. The source area SE2 and the drain area DE2 may extend from the active area AC2 in opposite directions, respectively, on the cross-section.

The oxide thin film transistor O-TFT disposed in the first area A1 may overlap the first lower light blocking layer BML1. Accordingly, light incident from below the display panel DP may be blocked by the first lower light blocking layer BML1 and may not be provided to the active area AC2 of the oxide thin film transistor O-TFT.

The oxide thin film transistor O-TFTa disposed in the second area A2 may not overlap the second lower light blocking layer BML2. Accordingly, a layer for blocking light incident on the bottom of the oxide thin film transistor O-TFTa may be added. For example, a third lower light blocking layer BML3 may be disposed under the oxide thin film transistor O-TFTa disposed in the second area A2. The third lower light blocking layer BML3 may be disposed between the second insulating layer 20 and the third insulating layer 30. The third lower light blocking layer BML3 may include the same material as the one electrode Csta of the first capacitor Cst (refer to FIG. 5) and may be formed through the same process as the one electrode Csta.

The fourth insulating layer 40 may be disposed on the third insulting layer 30. The fourth insulating layer 40 may cover the second semiconductor pattern. The fourth insulating layer 40 may be an inorganic layer and may have a single-layer structure or a multi-layer structure. The fourth insulating layer 40 may include at least one of aluminum oxide, titanium oxide, silicon oxide, silicon nitride, silicon oxy nitride, zirconium oxide, or hafnium oxide. In this example embodiment, the fourth insulating layer 40 may have a single-layer structure including silicon oxide.

A gate electrode GT2 of the oxide thin film transistor O-TFT or O-TFTa is disposed on the fourth insulating layer 40. The gate electrode GT2 may be a portion of a metal pattern. The gate electrode GT2 overlaps the active area AC2. The gate electrode GT2 may function as a mask in a process of reducing the second semiconductor pattern.

The fifth insulating layer 50 may be disposed on the fourth insulating layer 40 and may cover the gate electrode GT2. The fifth insulating layer 50 may be an inorganic layer and/or an organic layer and may have a single-layer structure or a multi-layer structure. For example, the fifth insulating layer 50 may have a multi-layer structure including a silicon oxide layer and a silicon nitride layer.

A first connecting electrode CNE10 may be disposed on the fifth insulating layer 50. The first connecting electrode CNE10 may be connected to the connecting signal line CSL through a first contact hole CH1 that penetrates the first to fifth insulating layers 10, 20, 30, 40, and 50.

A second opening ILop may be defined in the buffer layer BFL and at least some of the plurality of insulating layers 10, 20, 30, 40, 50, 60, 70, and 80 included in the circuit layer 130. For example, the second opening ILop may be defined in the buffer layer BFL and the first to fifth insulating layers 10, 20, 30, 40, and 50. The second opening ILop may be defined in the area overlapping the transmissive area TP. That is, as a portion of the buffer layer BFL and a portion of each of the first to fifth insulating layers 10, 20, 30, 40, and 50 that overlap the transmissive area TP is removed, the transmittance of the transmissive area TP may be improved.

The minimum width of the second opening ILop may be smaller than the minimum width of the first opening BMop. The sidewalls of the buffer layer BFL and the first to fifth insulating layers 10, 20, 30, 40, and 50 that define the second opening ILop may further protrude toward the transmissive area TP than the sidewall of the first lower light blocking layer BML1.

The sixth insulating layer 60 may be disposed on the fifth insulting layer 50. The sixth insulating layer 60 may include an organic material. The sixth insulating layer 60 may include a polyimide resin. For example, the sixth insulating layer 60 may include photosensitive polyimide. A second connecting electrode CNE20 may be disposed on the sixth insulating layer 60. The second connecting electrode CNE20 may be connected to the first connecting electrode CNE10 through a second contact hole CH2 that penetrates the sixth insulating layer 60.

The sixth insulating layer 60 may be disposed in both the light blocking area EP and the transmissive area TP. The sixth insulating layer 60 may be referred to as a common organic layer. The sixth insulating layer 60 may fill the portion where the second opening ILop is defined. That is, the sixth insulating layer 60 may overlap the transmissive area TP. Because the sixth insulating layer 60 is provided in the transmissive area TP, a step on the upper surface of the sixth insulating layer 60 may be decreased. When a step of layers overlapping the transmissive area TP is decreased, diffraction of light incident on the transmissive area TP may be alleviated (or reduced). Accordingly, the deformation of an image due to diffraction may be reduced, and thus the quality of an image obtained by the camera module CCM (refer to FIG. 2A) may be improved.

The seventh insulating layer 70 may be disposed on the sixth insulating layer 60 and may cover the second connecting electrode CNE20. The eighth insulating layer 80 may be disposed on the seventh insulting layer 70.

Each of the sixth insulating layer 60, the seventh insulating layer 70, and the eighth insulating layer 80 may be an organic layer. In this specification, the sixth insulating layer 60 may be referred to as a first organic insulating layer, the seventh insulating layer 70 may be referred to as a second organic insulating layer, and the eighth insulating layer 80 may be referred to as a third organic insulating layer. For example, each of the sixth insulating layer 60, the seventh insulating layer 70, and the eighth insulating layer 80 may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vynyl alcohol-based polymer, or a blend thereof.

Referring to FIGS. 8A and 8B, the element layer 140 that includes the first pixel electrode AE1, the light emitting element ED, the first pixel defining layer PDL1, and the second pixel defining layer PDL2 may be disposed on the circuit layer 130.

The first pixel electrode AE1 may be disposed in the first area A1, and the light emitting element ED may be disposed in the second area A2. The light emitting element ED may include a second pixel electrode AE2, a first functional layer HFL, an emissive layer EL, a second functional layer EFL, and the common electrode CE (or a cathode). The first functional layer HFL, the second functional layer EFL, and the common electrode CE may be commonly provided in the pixels PX.

The first pixel electrode AE1 and the second pixel electrode AE2 may be disposed on the eighth insulating layer 80. The first pixel electrode AE1 may be connected, for example, electrically connected with the first pixel circuit PDC1. The second pixel electrode AE2 may be electrically connected with the second pixel circuit PDC2. For example, the second pixel electrode AE2 may be connected to the second connecting electrode CNE20 through a third contact hole CH3 that penetrates the seventh insulating layer 70 and the eighth insulating layer 80.

The first pixel electrode AE1 is completely covered by the first pixel defining layer PDL1 to be described below and does not function as a light emitting element. Accordingly, the first pixel electrode AE1 may be referred to as a dummy electrode. The first pixel circuit PDC1 connected to the first pixel electrode AE1 that does not function as a light emitting element may be referred to as a dummy pixel circuit.

Each of the first pixel electrode AE1 and the second pixel electrode AE2 may be a (semi-) transmissive electrode or a reflective electrode. In an example embodiment, each of the first pixel electrode AE1 and the second pixel electrode AE2 may include a reflective layer formed of or including silver, magnesium, aluminum, platinum, palladium, gold, nickel, neodymium, iridium, chromium, or a compound thereof and a transparent or translucent electrode layer formed on the reflective layer. The transparent or translucent electrode layer may include at least one selected from the group consisting of indium tin oxide, indium zinc oxide, indium gallium zinc oxide, zinc oxide, or indium oxide and aluminum-doped zinc oxide. For example, each of the first pixel electrode AE1 and the second pixel electrode AE2 may include a multi-layer structure in which silver indium tin oxide, silver, and indium tin oxide are sequentially stacked.

The first pixel defining layer PDL1 and the second pixel defining layer PDL2 may be disposed on the eighth insulating layer 80. Each of the first pixel defining layer PDL1 and the second pixel defining layer PDL2 may have a property of absorbing light. For example, each of the first pixel defining layer PDL1 and the second pixel defining layer PDL2 may have a black color. Each of the first pixel defining layer PDL1 and the second pixel defining layer PDL2 may include a black coloring agent. The black coloring agent may include a black dye and a black pigment. The black coloring agent may include carbon black, metal such as chromium, or oxide thereof.

The first pixel defining layer PDL1 may be disposed in the first area A1 and may completely cover the first pixel electrode AE1. In addition, the first pixel defining layer PDL1 may cover the side surface of the eighth insulating layer 80 adjacent to the transmissive area TP. The first pixel defining layer PDL1 may be spaced apart from the side surface of the seventh insulating layer 70 adjacent to the transmissive area TP. Accordingly, the first pixel defining layer PDL1 may be stably brought into contact with the seventh insulating layer 70 and the eighth insulating layer 80.

A pixel defining opening PDLop that exposes a portion of the second pixel electrode AE2 may be defined in the second pixel defining layer PDL2. That is, the second pixel defining layer PDL2 may cover the periphery of the second pixel electrode AE2. Emissive areas may be defined by pixel defining openings PDLop defined in the second pixel defining layer PDL2. For example, an emissive area PXA may be defined in the light emitting element ED. In addition, because the first pixel defining layer PDL1 completely covers the first pixel electrode AE1, an emissive area may not be defined in the first pixel electrode AE1.

The first spacer HSPC may be disposed on the second pixel defining layer PDL2. The first protruding spacer SPC may be disposed on the first spacer HSPC. The first spacer HSPC and the first protruding spacer SPC may have a one-body shape (e.g., an integral body) and may be formed of the same material. For example, the first spacer HSPC and the first protruding spacer SPC may be formed through the same process using a half-tone mask. However, this is only an example, and example embodiments of the present disclosure are not limited thereto. For example, the first spacer HSPC and the first protruding spacer SPC may include different materials and may be formed through separate processes.

The second spacer UHSPC described with reference to FIG. 7 may have substantially the same thickness as the first spacer HSPC, and the second protruding spacer USPC described with reference to FIG. 7 may have substantially the same thickness as the first protruding spacer SPC. In addition, the cross-sectional shapes of the second spacer UHSPC and the second protruding spacer USPC may be similar to the cross-sectional shapes of the first spacer HSPC and the first protruding spacer SPC illustrated in FIG. 8B.

The first functional layer HFL may be disposed on the first pixel electrode AE1, the second pixel electrode AE2, the pixel defining layer PDL, the first spacer HSPC, and the first protruding spacer SPC. The first functional layer HFL may include a hole transport layer (HTL), may include a hole injection layer (HIL), or may include both the hole transport layer (HTL) and the hole injection layer (HIL).

The emissive layer EL may be disposed on the first functional layer HFL and may be disposed in the area corresponding to the pixel defining opening PDLop of the second pixel defining layer PDL2. The emissive layer EL may include an organic material, an inorganic material, or an organic-inorganic material that emits light of a certain color. The emissive layer EL may be disposed in the second area A2.

The second functional layer EFL may be disposed over the first functional layer HFL and may cover the emissive layer EL. The second functional layer EFL may include an electron transport layer (ETL), may include an electron injection layer (EIL), or may include both the electron transport layer (ETL) and the electron injection layer (EIL). The second functional layer EFL may be disposed in the second area A2.

The common electrode CE may be disposed on the second functional layer EFL. The common electrode CE may be disposed in the first area A1 and the second area A2. In an example embodiment of the present disclosure, the first pixel defining layer PDL1 may be disposed between the first pixel electrode AE1 and the common electrode CE. The electrode opening CEop overlapping the first opening BMop may be defined in the common electrode CE. The minimum width of the electrode opening CEop may be greater than the minimum width of the first opening BMop of the first lower light blocking layer BML1.

The element layer 140 may further include the capping layer CPL disposed on the common electrode CE. The capping layer CPL may serve to improve luminous efficiency by the principle of constructive interference. The capping layer CPL may include, for example, a material having a refractive index of about 1.6 or more for light having a wavelength of about 589 nm. The capping layer CPL may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be selectively substituted with a substituent including O, N, S, Se, Si, F, Cl, Br, I, or any combination thereof.

A portion of the capping layer CPL that overlaps the electrode opening CEop of the common electrode CE may be removed. As a portion of the capping layer CPL including a portion overlapping the transmissive area TP and a portion of the common electrode CE are removed, the light transmittance of the transmissive area TP may be further improved.

The encapsulation layer 150 may be disposed on the element layer 140. The encapsulation layer 150 may include a first inorganic encapsulation layer 151, an organic encapsulation layer 152, and a second inorganic encapsulation layer 153 sequentially stacked one above another. However, layers constituting the encapsulation layer 150 are not limited thereto.

The first inorganic encapsulation layer 151 and the second inorganic encapsulation layer 153 may protect the element layer 140 from moisture and oxygen, and the organic encapsulation layer 152 may protect the element layer 140 from foreign matter such as dust particles. The first inorganic encapsulation layer 151 and the second inorganic encapsulation layer 153 may include a silicon nitride layer, a silicon oxy nitride layer, a silicon oxide layer, a titanium oxide layer, or an aluminum oxide layer. The organic encapsulation layer 152 may include an acrylic organic layer, but is not limited thereto.

In an example embodiment of the present disclosure, the maximum thickness 152TK1 of a portion of the organic encapsulation layer 152 that overlaps the first area A1 may be greater than the maximum thickness 152TK2 of a portion of the organic encapsulation layer 152 that overlaps the second area A2.

The sensor layer 200 may be disposed on the display layer 100. The sensor layer 200 may be referred to as a sensor, an input sensing layer, or an input sensing panel. The sensor layer 200 may include a sensor base layer 210, a first sensor conductive layer 220, an intermediate insulating layer 230, a second sensor conductive layer 240, and a cover layer 250.

The sensor base layer 210 may be directly disposed on the display layer 100. The sensor base layer 210 may be an inorganic layer including at least one of silicon nitride, silicon oxy nitride, or silicon oxide. In some example embodiments, the sensor base layer 210 may be an organic layer including an epoxy resin, an acrylic resin, or an imide-based resin. The sensor base layer 210 may have a single-layer structure or may have a multi-layer structure stacked in the third direction DR3.

Each of the first sensor conductive layer 220 and the second sensor conductive layer 240 may have a single-layer structure or may have a multi-layer structure stacked in the third direction DR3.

A conductive layer having a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide, indium zinc oxide, zinc oxide, or indium zinc tin oxide. In addition, the transparent conductive layer may include a conductive polymer, such as PEDOT, a metal nano wire, or graphene.

A conductive layer having a multi-layer structure may include metal layers. The metal layers may have, for example, a three-layer structure of titanium/aluminum/titanium. The conductive layer having the multi-layer structure may include at least one metal layer and at least one transparent conductive layer.

The intermediate insulating layer 230 may be disposed between the first sensor conductive layer 220 and the second sensor conductive layer 240. The intermediate insulating layer 230 may include an inorganic film. The inorganic film may include at least one of aluminum oxide, titanium oxide, silicon oxide, silicon nitride, silicon oxy nitride, zirconium oxide, or hafnium oxide.

In some example embodiments, the intermediate insulating layer 230 may include an organic film. The organic film may include at least one of an acrylic resin, a methacrylic resin, a polyisoprene resin, a vinyl resin, an epoxy resin, a urethane-based resin, a celluosic resin, a siloxane-based resin, a polyimide resin, a polyamide resin, or a perylene-based resin.

The cover layer 250 may be disposed on the intermediate insulating layer 230 and may cover the second sensor conductive layer 240. The second sensor conductive layer 240 may include a conductive pattern. The cover layer 250 may cover the conductive pattern and may reduce or eliminate the probability of damage to the conductive pattern in a subsequent process.

The cover layer 250 may include an inorganic material. For example, the cover layer 250 may include silicon nitride, but is not particularly limited thereto.

The anti-reflective layer 300 may be disposed on the sensor layer 200. The anti-reflective layer 300 may include the division layer 310, a plurality of color filters 320, and a planarization layer 330. The division layer 310 and the color filters 320 are not disposed in the transmissive area TP of the first area A1.

In an example embodiment of the present disclosure, the division layer 310 may be omitted. In this case, the function of the division layer 310 may be replaced by the color filters 320. The cover layer 250 may be disposed between the division layer 310 and the second sensor conductive layer 240. The division layer 310 may reduce or prevent reflection of external light by the second sensor conductive layer 240. The material constituting the division layer 310 is not particularly limited as long as it is a material that absorbs light. The division layer 310 may be a layer having a black color. In an example embodiment, the division layer 310 may include a black coloring agent. The black coloring agent may include a black dye and a black pigment. The black coloring agent may include carbon black, a metal such as chromium, or oxide thereof.

A division opening 310op and a transmissive opening 310opt may be defined in the division layer 310. The division opening 310op may overlap the second pixel electrode AE2. For reference, the planar shape of the division layer 310 is illustrated in FIG. 9. In addition, the division layer 310 may overlap the first pixel electrode AE1. That is, an opening may not be defined in an area of the division layer 310 that overlaps the first pixel electrode AE1.

The color filter 320 may be disposed to overlap the division opening 310op. The color filter 320 may transmit light provided from the emissive layer EL overlapping the color filter 320.

The transmissive opening 310opt of the division layer 310 may overlap the first opening BMop of the first lower light blocking layer BML1. In addition, the transmissive opening 310opt may not overlap the first pixel electrode AE1. The minimum width of the transmissive opening 310opt of the division layer 310 may be substantially the same as the minimum width of the first opening BMop of the first lower light blocking layer BML1. That is, in an area adjacent to the transmissive area TP, an end of the division layer 310 may be substantially aligned with an end of the first lower light blocking layer BML1. Meanwhile, in this specification, when components are “substantially aligned with each other” or the widths of the components are “substantially the same as each other,” this means not only that the components are completely aligned with each other or the widths of the components have the same physical size, but also that the widths of the components are the same within an error range occurring during a process even though the widths of the components are designed to be the same.

In the area adjacent to the transmissive area TP, the end of the division layer 310 may further protrude toward the transmissive area TP than an end of the first pixel defining layer PDL1 and an end of the common electrode CE.

The planarization layer 330 may cover the division layer 310 and the color filters 320. The planarization layer 330 may include an organic material and may provide a flat surface on the upper surface of the planarization layer 330. In an example embodiment, the planarization layer 330 may be omitted.

FIG. 9 is an enlarged plan view of a partial area of a display panel according to an example embodiment of the present disclosure. FIG. 9 is an enlarged plan view of area XX′ illustrated in FIG. 6.

Referring to FIGS. 8A, 8B, and 9, a plurality of division openings 310op and a plurality of transmissive openings 310opt may be defined in the division layer 310.

The division openings 310op defined in the second area A2 may overlap the emissive areas PXA in a one-to-one correspondence. In addition, the division openings 310op may overlap the second pixel electrodes AE2 in a one-to-one correspondence.

The transmissive opening 310opt may overlap the first opening BMop of the first lower light blocking layer BML1. The transmissive opening 310opt may have substantially the same size as the first opening BMop of the first lower light blocking layer BML1.

Some of the first pixel electrodes AE1 disposed in the first area A1 may be covered by the first pixel defining layer PDL1, and the other first pixel electrodes AE1 may be covered by the second pixel defining layer PDL2. The other first pixel electrodes AE1 may be disposed adjacent to the second area A2 and may be disposed between the transmissive areas TP and the second area A2. In addition, the first pixel electrodes AE1 disposed in the first area A1 may all be covered by the division layer 310.

The camera module CMM may be disposed to overlap the first area A1. The camera module CMM may take an external image through the transmissive areas TP provided in the first area A1.

According to an example embodiment of the present disclosure, the transmissive areas TP may be provided in the first area A1 overlapping the camera module CMM. The transmissive areas TP may overlap the base layer 110 and the barrier layer 120. That is, the first area A1 overlapping the camera module CMM may not be removed by a cutting process, for example, a cutting process using a laser. Because the boundary between the first area A1 and the second area A2 is not exposed to the outside in this case, a path itself along which moisture penetrates from the boundary between the first area A1 and the second area A2 may not be provided. Accordingly, deterioration in product reliability due to side moisture penetration, for example, a decrease in luminance due to oxidation of the emissive layer EL and/or shrinkage of layers included in the display panel DP due to moisture penetration may not occur. Thus, the product reliability of the electronic device EDE (refer to FIG. 3A) may be improved.

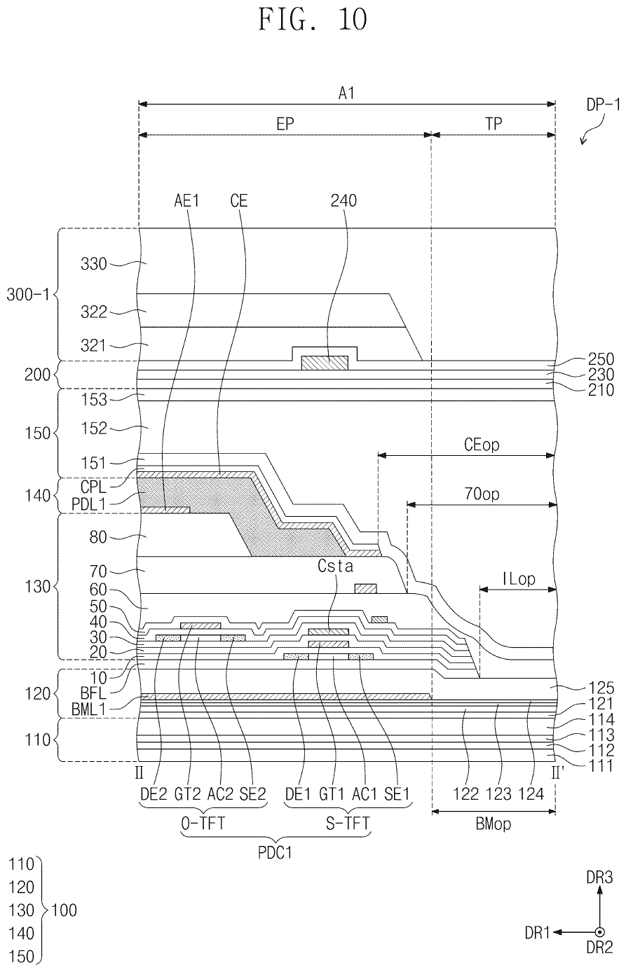

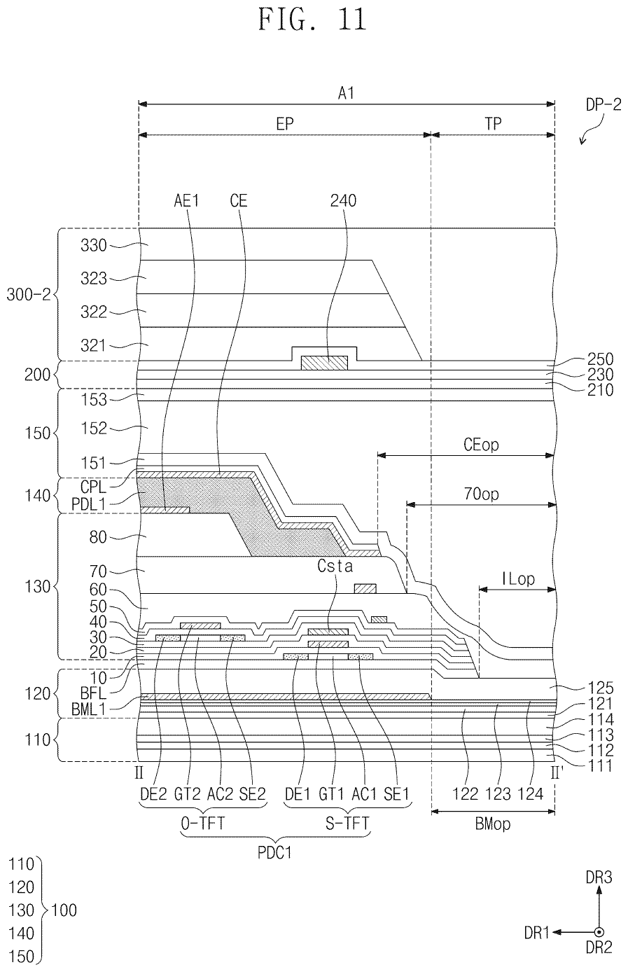

FIG. 10 is a sectional view illustrating a first area A1 of a display panel DP-1 according to an example embodiment of the present disclosure. FIG. 10 illustrates a cross-section corresponding to line cutting line II-II′ of FIG. 7. In describing FIG. 10, components identical to the components described with reference to FIG. 8A will be assigned with identical reference numerals, and description thereabout will be omitted.

Referring to FIG. 10, the display panel DP-1 may include an anti-reflective layer 300-1. The anti-reflective layer 300-1 may include a first color filter 321 and a second color filter 322 having a color different from that of the first color filter 321.

In an example embodiment of the present disclosure, at least two color filters 321 and 322 may be disposed to overlap a first pixel electrode AE1 and may not overlap a transmissive area TP. For example, the first color filter 321 may be disposed to overlap the first pixel electrode AE1, and the second color filter 322 may be disposed on the first color filter 321.

In an example embodiment of the present disclosure, the first color filter 321 and the second color filter 322 may have different colors. Accordingly, the first color filter 321 and the second color filter 322 may overlap each other and may function as a light blocking layer.

In an example embodiment of the present disclosure, the first color filter 321 and the second color filter 322 may include a red color filter and a blue color filter, but are not particularly limited thereto. For example, the first color filter 321 and the second color filter 322 may include two color filters selected from a red color filter, a blue color filter, and a green color filter.

FIG. 11 is a sectional view illustrating a first area A1 of a display panel DP-2 according to an example embodiment of the present disclosure. FIG. 11 is a sectional view corresponding to cutting line II-II′ of FIG. 7. In describing FIG. 11, components identical to the components described with reference to FIG. 8A will be assigned with identical reference numerals, and description thereabout will be omitted.

Referring to FIG. 11, the display panel DP-2 may include an anti-reflective layer 300-2. The anti-reflective layer 300-2 may include a first color filter 321, a second color filter 322 having a color different from that of the first color filter 321, and a third color filter 323 having a color different from those of the first color filter 321 and the second color filter 322.

In an example embodiment of the present disclosure, at least two color filters 321, 322, and 323 may be disposed to overlap a first pixel electrode AE1 and may not overlap a transmissive area TP. For example, the first color filter 321 may be disposed to overlap the first pixel electrode AE1, the second color filter 322 may be disposed on the first color filter 321, and the third color filter 323 may be disposed on the second color filter 322.

In an example embodiment of the present disclosure, the first color filter 321, the second color filter 322, and the third color filter 323 may have different colors. Accordingly, the first color filter 321, the second color filter 322, and the third color filter 323 may overlap one another and may function as a light blocking layer. Accordingly, the first color filter 321, the second color filter 322, and the third color filter 323 may be a red color filter, a blue color filter, and a green color filter.

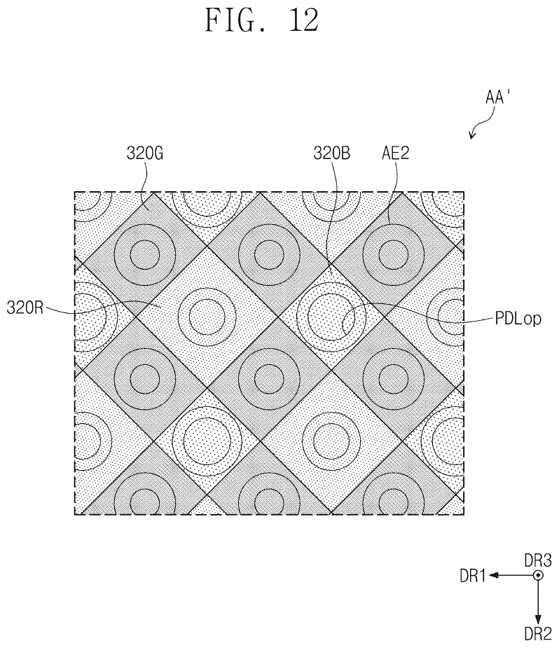

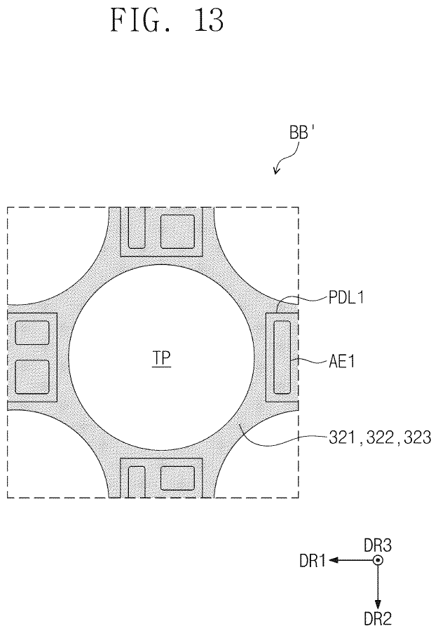

FIG. 12 is an enlarged plan view of a partial area of a display panel according to an example embodiment of the present disclosure. FIG. 13 is an enlarged plan view of a partial area of the display panel according to an example embodiment of the present disclosure. The area illustrated in FIG. 12 may be an area corresponding to area AA′ of FIG. 9. The area illustrated in FIG. 13 may be an area corresponding to area BB′ of FIG. 9.

Referring to FIGS. 8B, 10, 11, and 12, the plurality of color filters 320 may include color filters 320R, 320G, and 320B disposed in the second area A2. The color filters 320R, 320G, and 320B may include the first color filter 320R, the second color filter 320G, and the third color filter 320B.

When the anti-reflective layer 300 (refer to FIG. 8B) includes the division layer 310, the first to third color filters 320R, 320G, and 320B may overlap the division openings 310op of the division layer 310 in a one-to-one correspondence. When the anti-reflective layer 300-1 (refer to FIG. 10) does not include the division layer 310, the first to third color filters 320R, 320G, and 320B may overlap the pixel defining openings PDLop of the second pixel defining layer PDL2 in a one-to-one correspondence. In addition, the first to third color filters 320R, 320G, and 320B may overlap the second pixel electrodes AE2 in a one-to-one correspondence.

The shape of each of the division openings 310op may be different from the shape of each of the first to third color filters 320R, 320G, and 320B. The shape of each of the pixel defining openings PDLop may be different from the shape of each of the first to third color filters 320R, 320G, and 320B. When viewed from above the plane, the pixel defining openings PDLop and the division openings 310op may have a circular shape, and the first to third color filters 320R, 320G, and 320B may have a quadrangular shape.

FIG. 13 is an enlarged plan view of a partial area of a display panel according to an example embodiment of the present disclosure. The area illustrated in FIG. 13 may be an area corresponding to area BB′ of FIG. 9.

Referring to FIGS. 10, 11, and 13, the shapes of the first color filter 321, the second color filter 322, and the third color filter 323 are illustrated in FIG. 13. The first color filter 321, the second color filter 322, and the third color filter 323 may have substantially the same shape and may overlap one another in the first area A1. According to the example embodiment of FIG. 10, one of the first color filter 321, the second color filter 322, and the third color filter 323 may be omitted.

Each of the first color filter 321, the second color filter 322, and the third color filter 323 may have an opening corresponding to the transmissive area TP and may not overlap the transmissive area TP. In addition, each of the first color filter 321, the second color filter 322, and the third color filter 323 may overlap all of the first pixel electrodes AE1.

As described above, the transmissive areas may be provided in the first area overlapping the camera module and may overlap the base layer and the barrier layer. That is, the first area overlapping the camera module may not be removed by a cutting process, for example, a cutting process using a laser. Because the boundary between the first area and the second area of the display panel is not exposed to the outside in this case, a path itself along which moisture penetrates from the boundary between the first area and the second area may not be provided. Accordingly, deterioration in product reliability due to side moisture penetration, for example, a decrease in luminance due to oxidation of the emissive layer and/or shrinkage of layers included in the display panel due to moisture penetration may not occur. Thus, the product reliability of the electronic device may be improved.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a display panel including a first area and a second area adjacent to the first area, the first area including a transmissive area and a light blocking area; and
an electronic module under the display panel and overlapping the first area,
wherein the display panel includes
a first pixel electrode in the light blocking area of the first area,
a second pixel electrode in the second area,
a first pixel defining layer in the first area and configured to completely cover the first pixel electrode, and
a second pixel defining layer in the second area and including a pixel defining opening corresponding to the second pixel electrode.

2. The electronic device of claim 1, wherein
the display panel further includes a division layer, the division layer being on the first pixel defining layer and the second pixel defining layer, and
the division layer includes a division opening that is configured to overlap the second pixel electrode.

3. The electronic device of claim 2, wherein
the division layer further includes a transmissive opening that is configured to overlap the transmissive area, and
the division layer overlaps the first pixel electrode.

4. The electronic device of claim 1, further comprising:
at least two color filters configured to overlap the first pixel electrode.

5. The electronic device of claim 4, wherein the at least two color filters have different colors.

6. The electronic device of claim 4, wherein the at least two color filters do not overlap the transmissive area.

7. The electronic device of claim 4, wherein the at least two color filters include a red color filter and a blue color filter.

8. The electronic device of claim 4, wherein the at least two color filters include a red color filter, a blue color filter, and a green color filter.

9. The electronic device of claim 1, wherein the display panel further includes
a common electrode on the first pixel electrode and the second pixel electrode, and
an emissive layer between the second pixel electrode and the common electrode.

10. The electronic device of claim 9, wherein the first pixel defining layer is between the first pixel electrode and the common electrode.

11. The electronic device of claim 1, wherein the display panel further includes
a dummy pixel circuit in the first area and connected with the first pixel electrode and
a pixel circuit in the second area and electrically connected with the second pixel electrode.

12. An electronic device comprising:
a base layer having a first area and a second area defined therein;
a circuit layer on the base layer;
an element layer on the circuit layer, the element layer including
a first pixel electrode in the first area,
a second pixel electrode in the second area,
a first pixel defining layer in the first area and configured to completely cover the first pixel electrode, and
a second pixel defining layer in the second area and including a pixel defining opening corresponding to the second pixel electrode; and
an encapsulation layer on the element layer.

13. The electronic device of claim 12, further comprising:
an anti-reflective layer on the encapsulation layer,
wherein the anti-reflective layer includes a color filter and is configured to overlap the second pixel electrode.

14. The electronic device of claim 13, wherein the anti-reflective layer further includes a first color filter configured to overlap the first pixel electrode and a second color filter having a color different from a color of the first color filter, the second color filter being on the first color filter.

15. The electronic device of claim 14, wherein the anti-reflective layer further includes a third color filter configured to overlap the first pixel electrode and being on the second color filter, the third color filter having a color different from colors of the first color filter and the second color filter.

16. The electronic device of claim 13, wherein
the anti-reflective layer further includes a division layer,
the division layer includes a division opening configured to overlap the second pixel electrode, and
the division layer overlaps the first pixel electrode.

17. The electronic device of claim 16, wherein the division layer further includes a transmissive opening that does not overlap the first pixel electrode.

18. The electronic device of claim 12, further comprising:
an electronic module under the base layer and configured to overlap the first area.

19. The electronic device of claim 12, wherein
the encapsulation layer includes a first inorganic encapsulation layer, an organic encapsulation layer on the first inorganic encapsulation layer, and a second inorganic encapsulation layer on the organic encapsulation layer, and
a maximum thickness of a portion of the organic encapsulation layer configured to overlap the first area is greater than a maximum thickness of a portion of the organic encapsulation layer configured to overlap the second area.

20. The electronic device of claim 12, wherein the circuit layer includes a dummy pixel circuit in the first area and connected with the first pixel electrode and a pixel circuit in the second area and electrically connected with the second pixel electrode.
